(19) United States
(12) Patent Application Publication
(10) Pub. No.: US 2025/0206596 A1
(43) Pub. Date: Jun. 26, 2025

(54) NANO ELECTROMECHANICAL DEVICE AND MANUFACTURING METHOD THEREOF

(71) Applicant: SEOUL NATIONAL UNIVERSITY R&DB FOUNDATION, Seoul (KR)

(72) Inventors: Woo Young CHOI, Seoul (KR); Jin Wook LEE, Seoul (KR)

(73) Assignee: SEOUL NATIONAL UNIVERSITY R&DB FOUNDATION, Seoul (KR)

(21) Appl. No.: 18/790,360

(22) Filed: Jul. 31, 2024

(30) Foreign Application Priority Data
Dec. 22, 2023 (KR) 10-2023-0190086
Jun. 3, 2024 (KR) 10-2024-0072633

(51) Int. Cl. B81B 3/00; B81C 1/00

(52) U.S. Cl. CPC B81B 3/0072; B81C 1/00666; B81B 2203/0118; B81B 2203/0307; B81B 2203/04; B81B 2203/056; B81B 2207/07; B81C 2201/013

(57) ABSTRACT

A nano electromechanical device includes: a first electrode formed on an upper portion of a metal wiring layer; a second electrode spaced apart from the first electrode and arranged in parallel; a movable beam arranged between the first electrode and the second electrode and moving horizontally to contact the first electrode or the second electrode; and a via anchor connected to upper and lower portions of one side of the movable beam and supporting the movable beam. Therefore, the present disclosure can improve the durability of the device, operate at low driving voltage, and improve integration.

### CROSS-REFERENCE TO PRIOR APPLICATIONS

This application claims priority to Korean Patent Application Nos. 10-2023-0190086 (filed on Dec. 22, 2023) and 10-2024-0072633 (filed on Jun. 3, 2024), which are all hereby incorporated by reference in their entirety.

### ACKNOWLEDGEMENT

### National Research Development Project Supporting the Present Invention

[Project Serial No.] 1711182048
[Project No.] 2022M3F3A2A01073944
[Department] Ministry of Science and ICT, Republic of Korea
[Project Management (Professional) National Research Foundation of Korea
[Research Project Name] Development of Next-generation Intelligent Semiconductor Technology (Devices)
[Research Task Name] Development of NEM Associative Memory-augmented Neural Network Based on CMOS Wiring Technology
[Project Performing Institute] Seoul National University R&DB Foundation [Research Period] 2023.01.01 to 2023.12.31

### National Research Development Project Supporting the Present Invention

[Project Serial No.] 1711187103
[Project No.] 2021R1A2C1007931
[Department] Ministry of Science and ICT, Republic of Korea
[Project Management (Professional) Institute] National Research Foundation of Korea
[Research Project Name] Individual Basic Research (Ministry of Science and ICT)
[Research Task Name] Development of Brain-mimicking Computing Technology Using Monolithic Three-dimensional Integration of Ultra-low Power Non-volatile Memory Devices
[Project Performing Institute] Seoul National University R&DB Foundation
[Research Period] 2023.03.01 to 2024.02.29

### BACKGROUND

The present disclosure relates to a nano electromechanical device and a manufacturing method thereof, and more particularly, to a nano electromechanical device in which upper and lower portions of an end portion of one side of a movable beam are fixed to a via anchor, and a manufacturing method thereof.

Recently, market demand for ultra-low power, highly integrated memory has been increasing exponentially. However, the existing memory device is implemented using a complementary metal-oxide-semiconductor (CMOS) process technology, which results in area loss, performance degradation, and yield reduction. To overcome this problem, various low-power, high-energy-efficiency memory devices have recently been researched. In particular, research is being actively conducted on nano electromechanical devices in which devices are constructed and integrated on metal wiring layers on ICs rather than the existing semiconductor devices.

Compared to their excellent electrical performance, nano electromechanical devices have a weak switching cycle, that is, weak durability, which severely limits their applications. The existing nano electromechanical devices show a sharp increase in driving voltage as the switching cycle is repeated. This is because the stress concentrated on an anchor part of a movable beam is excessive, causing material fatigue to accumulate. As a result, a softening phenomenon occurs and thus resilience is weakened. When this phenomenon is repeated, mechanical defects such as breakage of movable beams may occur. Therefore, the nano electromechanical devices having the existing structures require a solution capable of securing the durability and suppressing the increase in driving voltage.

### RELATED ART DOCUMENT

Korean Patent No. 10-1383760 (Apr. 3, 2014)

### SUMMARY

In view of the above, the present disclosure provides a nano electromechanical device capable of implementing an ultra-low-power non-volatile memory device, which can be three-dimensionally integrated, on existing semiconductor chips with a simple process and low cost, improving device durability through an improved structure, and being implemented in a smaller area.

The present disclosure provides a nano electromechanical device capable of maximizing low-power non-volatile memory characteristics by operating at a lower driving voltage than the existing one.

The present disclosure provides a nano electromechanical device having a via anchor structure using a mechanical torsion, and a manufacturing process thereof.

According to an aspect of the present disclosure, a nano electromechanical device includes: a first electrode formed on an upper portion of a metal wiring layer; a second electrode spaced apart from the first electrode and arranged in parallel; a movable beam arranged between the first electrode and the second electrode and moving horizontally to contact the first electrode or the second electrode; and a via anchor connected to upper and lower portions of one side of the movable beam and supporting the movable beam.

The via anchor may include: a lower via anchor connected to a lower end of one side of the movable beam; and an upper via anchor connected to an upper end of one side of the movable beam and arranged on a vertical line to the lower via anchor.

The lower via anchor may be formed in a first via anchor region defined at a lower portion of the semiconductor structure and formed by burying a conductive material in a lower via anchor supporter formed of a first insulating film.

The upper via anchor may be formed in a second via anchor region defined at an upper portion of the semiconductor structure and may be formed by burying a conductive material in an upper via anchor supporter formed of a second insulating film.

When a positive voltage is applied to the first electrode or the second electrode, the movable beam may move in a direction of the first electrode or the second electrode by electromagnetic force applied between the electrodes to be connected to the corresponding electrode.

The via anchor may be torsioned at a certain angle in the corresponding direction during a pull-in operation in which the movable beam moves in the direction of the first electrode or the second electrode.

The via anchor may be torsionable and support horizontal movement of the movable beam through the torsion.

When the movable beam operates, deformation occurring in the movable beam may be distributed to the via anchor as the torsion.

When a structure of the via anchor is replaced with a spring model, it may have a serial structure of a linear spring constant K_{beam} of the movable beam and a spring constant K_{via′} derived from the torsional stiffness of the via anchor.

A method of manufacturing a nano electromechanical device includes: forming a first insulating film on an upper portion of a semiconductor structure; forming a lower via anchor and a movable beam by etching the first insulating film and burying a conductive material; forming a second insulating film on an entire upper portion; and forming an upper via anchor by etching the second insulating film and burying the conductive material.

The forming of the lower via anchor and the movable beam may include forming a lower via anchor region by etching the first insulating film to expose a lower metal wiring included in the semiconductor structure.

The forming of the lower via anchor and the movable beam may include forming a movable beam region extending in the same direction as the lower metal wiring from an upper portion of the lower via anchor region by etching the first insulating film.

The forming of the lower via anchor and the movable beam may include burying and planarizing a conductive material in the lower via anchor region and the movable beam region.

The forming of the upper via anchor may include forming an upper via anchor region on a vertical line to the lower via anchor by etching the second insulating film.

The forming of the upper via anchor may include forming an upper metal wiring region on an upper portion of the upper via anchor region by etching the second insulating film, and burying and planarizing a conductive material in the upper via anchor region and the upper metal wiring region.

The method may further include: forming an air gap around the movable beam by etching the first insulating film and the second insulating film to expose a side surface of the lower via anchor and an upper end of the movable beam.

According to another aspect of the present disclosure, a method of manufacturing a nano electromechanical device includes: forming a lower metal wiring on an upper portion of a semiconductor structure and forming a first insulating film on an entire upper portion including the lower metal wiring; forming a first via anchor region and a movable beam region by etching the first insulating film; forming a lower via anchor and a movable beam by burying a conductive material in the first via anchor region and the movable beam region; forming a second insulating film on the entire upper portion and forming a second via anchor region and an upper metal wiring region by etching the second insulating film; forming an upper via anchor and an upper metal wiring by burying the conductive material in the second via anchor region and the upper metal wiring region; and forming an air gap at regular intervals around the movable beam by etching the first insulating film and the second insulating film adjacent to the movable beam.

The semiconductor structure may include a plurality of metal wirings.

The lower via anchor and the upper via anchor may be formed on a vertical line.

The lower via anchor and the upper via anchor may be formed to contact one side of the movable beam.

The disclosed technology may have the following effects. However, since a specific embodiment is not construed as including all of the following effects or only the following effects, it should not be understood that the scope of the disclosed technology is limited to the specific embodiment.

According to the nano electromechanical device and manufacturing method thereof according to the embodiment of the present disclosure, as the stress caused by the deformation in the movable beam anchor part having the T-shaped structure is distributed using the torsions of the upper and lower via anchors, it is possible to improve the device durability.

In addition, since the torsion of the via anchor helps the movement of the movable beam, by enabling operation at a lower driving voltage and reducing the length of the movable beam, it is possible to manufacture the smaller-sized nano electromechanical device.

In addition, by replacing the area of the movable beam anchor part having the T-shaped structure with the upper and lower via anchors, it is possible to be easily integrated vertically into each metal layer and increase the device integration.

### BRIEF DESCRIPTION OF THE DRAWINGS

FIG. 1 is a diagram illustrating a nano electromechanical device according to an embodiment of the present disclosure.

FIGS. 2A to 2E are diagrams illustrating a method of manufacturing a nano electromechanical device according to an embodiment of the present disclosure.

FIG. 3 is a diagram illustrating an operating state of the nano electromechanical device according to the embodiment of the present disclosure.

FIG. 4 is a diagram illustrating a degree of stress applied to an anchor part of the nano electromechanical device according to the embodiment of the present disclosure.

FIG. 5 is a diagram for describing linear spring modeling of the nano electromechanical device according to an embodiment of the present disclosure.

FIG. 6 is a diagram illustrating the effect of a via anchor of the nano electromechanical device on a movable beam according to the embodiment of the present disclosure.

FIG. 7 is a diagram for describing the state of the nano electromechanical device according to the embodiment of the present disclosure.

### DETAILED DESCRIPTION

The description of the present disclosure is only an embodiment for structural or functional explanation, the scope of the present disclosure should not be construed as limited by the embodiment described herein. In other words, since the embodiment can be modified in various ways and can have various forms, the scope of the present disclosure should be understood to include equivalents that can realize the technical idea. In addition, the objects or effects presented in the present specification does not mean that a specific embodiment should include all of them or only those effects, so the scope of the present disclosure should not be understood to be limited thereby.

Meanwhile, the meaning of the terms described in the present specification should be understood as follows.

The terms such as “first,” “second,” etc. are used to distinguish one component from another, and the scope of the present disclosure should not be limited by these terms. For example, a first component may be named a second component, and similarly, the second component may also be named the first component.

When a component is referred to as being “connected” to another component, it should be understood that it may be directly connected to the other component, but that other components may also exist between them. On the other hand, when a component is referred to be as being “directly connected” to another component, it should be understood that there are no other components between them. Meanwhile, other expressions that describe the relationship between components, such as “between” and “immediately between” or “adjacent to” and “directly adjacent to”, should be interpreted similarly.

Singular expressions should be understood to include plural expressions unless the context clearly indicates otherwise, and terms such as “include” or “have” are intended to designate that the presence of a feature, number, step, operation, component, part, or combination thereof, and should be understood as not excluding in advance the possibility of the presence or addition of one or more other features, numbers, steps, operations, components, parts, or combinations thereof.

For each step, identification codes (e.g., a, b, c, etc.) are used for convenience of explanation. The identification codes do not describe the order of steps, and the steps may occur in any order other than that specified unless the context clearly indicates a specific order. That is, the steps may occur in the same order as specified, may be performed substantially simultaneously, or may be performed in the opposite order.

All terms used herein, unless otherwise defined, have the same meaning as commonly understood by a person of ordinary skill in the field to which the present disclosure pertains. The terms defined in commonly used dictionaries should be interpreted as consistent with the their meaning in the context of the related art, and are not to be interpreted as having an idealized or unduly formal meaning unless expressly defined in the present specification.

Hereinafter, with reference to the accompanying drawings, preferred embodiments of the present disclosure will be described in more detail. In the description of the present disclosure, the same reference numerals are used for the same components in the drawings, and redundant descriptions of the same components are omitted.

Generally, a nano electromechanical device has three states: an initial state, a first state (state 1), and a second state (state 2). First, when the movable beam is not attached to any electrode, it is in the initial state (initial), when the movable beam is attached to a first electrode L1, it is in the first state (state 1), and when the movable beam is attached to the second electrode L2, it is in the second state (state 2). This serves as a non-volatile memory that stores each state using the principle of mechanical movement. The stored state is determined by the position of the movable beam of the nano electromechanical memory switch. In the initial state, the movable beam does not contact the first electrode L1 or the second electrode L2. Then, when a positive voltage V_{L1} or V_{L2} is applied to the first electrode L1 or the second electrode L2, the movable beam moves to the first electrode L1 or the second electrode L2 by the electromagnetic force applied between the metal electrodes and connects to the corresponding electrode. The state is maintained and stored semi-permanently between the connected movable beam and the electrode without any additional external force by the attractive force acting on surfaces of materials in contact with each other, such as van der Waals attraction. This non-volatility allows the electromechanical memory device to achieve ultra-low-power memory characteristics.

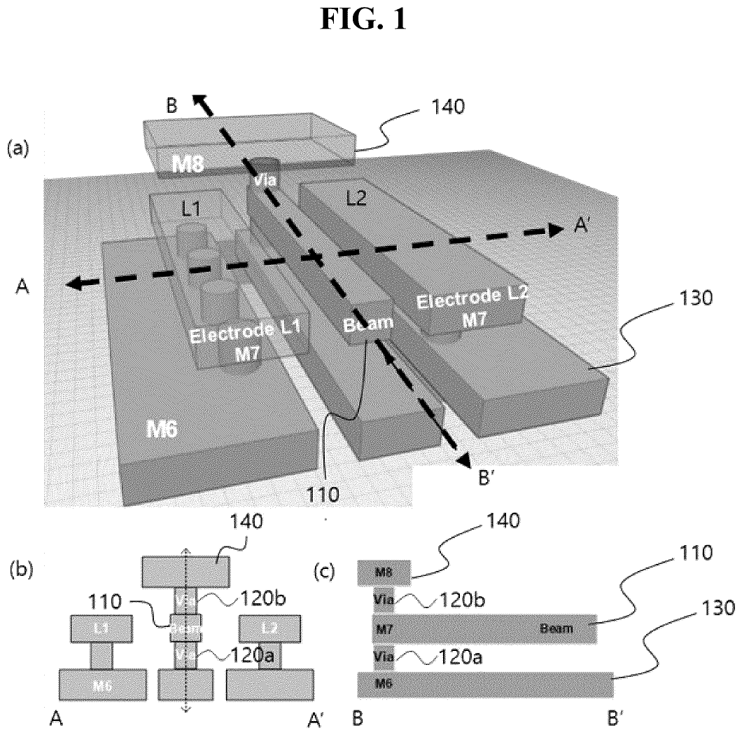

FIG. 1 is a diagram illustrating a nano electromechanical device according to an embodiment of the present disclosure. FIG. 1, (a) is a perspective view, (b) is a cross-sectional view taken along A-A′, and (c) is a cross-sectional view taken along B-B′.

Referring to FIG. 1, the nano electromechanical device may include the first electrode L1 and the second electrode L2, a movable beam 110, and a via anchor 120.

The first electrode L1 is formed on the metal wiring layer. The second electrode L2 is spaced apart from the first electrode L1 and is arranged in parallel.

The first electrode L1 and the second electrode L2 are each connected to lower metal wirings 130 through a plurality of vias. The first electrode L1 and the second electrode L2 are spaced apart from each other at a predetermined distance and arranged in parallel.

The movable beam 110 is arranged between the first electrode L1 and the second electrode L2 and moves horizontally to contact the first electrode L1 or the second electrode L2. One end portion of the movable beam 110 is fixed by the via anchor 120 and connected to the lower metal wiring 130 and the upper metal wiring 140. The horizontal movement of the movable beam 110 fixed through the via anchor 120 may contact the first electrode L1 or the second electrode L2 and change to the first state (state 1) or the second state (state 2), respectively. When a positive voltage is applied to the first electrode L1 or the second electrode L2, the movable beam 110 may move to the first electrode L1 or the second electrode L2 by the electromagnetic force applied between the electrodes and may be connected to the corresponding electrode.

The movable beam 110 may extend in the same direction as the lower metal wiring 130 and may extend in a direction vertically intersecting the upper metal wiring 140. Here, the lower metal wiring 130 and the upper metal wiring 140 may be formed through the same process as the CMOS metal wire.

The via anchor 120 is connected to the upper and lower portions of one side of the movable beam 110 and supports the movable beam 110. The via anchor 120 may include a lower via anchor 120a connected to a lower end of one side of the movable beam 110 and an upper via anchor 120b connected to an upper end of one side of the movable beam 110. Here, the upper via anchor 120b may overlap the lower via anchor 120a and be placed on a vertical line, but is not necessarily limited thereto and may be formed in a form that partially overlaps or does not overlap the lower via anchor 120a.

The lower via anchor 120a may be formed in a first via anchor region defined at a lower portion of a semiconductor structure and formed by burying a conductive material in a lower via anchor supporter formed of a first insulating film. In addition, the upper via anchor 120b may be formed in a second via anchor region defined at an upper portion of the semiconductor structure and formed by burying a conductive material in an upper via anchor supporter formed of a second insulating film.

The via anchor 120 can be torsioned at a certain angle along the moving direction of the movable beam 110, and in this case, the degree of torsion of the lower via anchor 120a and the upper via anchor 120b may be different. The via anchor 120 may be torsioned at a certain angle in the corresponding direction during a pull-in operation in which the movable beam 110 moves in the direction of the first electrode L1 or the second electrode L2. The via anchor 120 can be torsioned and support horizontal movement of the movable beam 110 through the torsion.

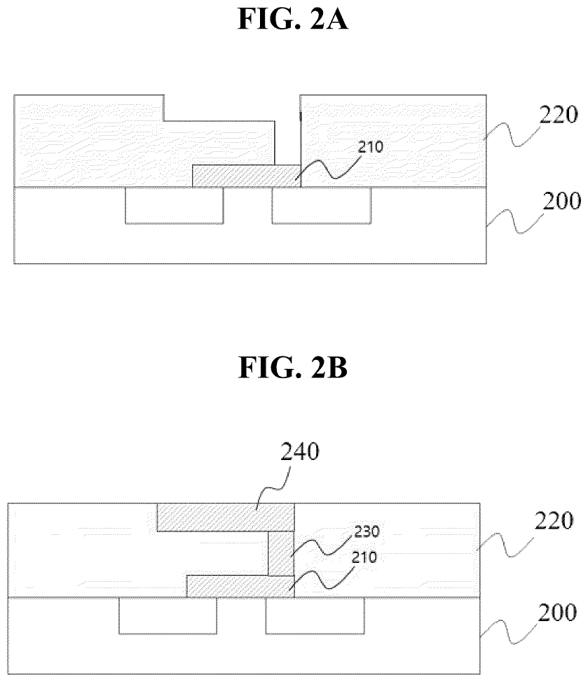

FIGS. 2A to 2E are cross-sectional views illustrating a method of manufacturing a nano electromechanical device according to an embodiment of the present disclosure.

First, referring to FIG. 2A, a lower metal wiring 210 is formed on the upper portion of the semiconductor structure 200, and a first insulating film 220 is formed on the entire upper portion including the lower metal wiring 210. In this case, the semiconductor structure 200 may include a plurality of metal wirings, etc. Thereafter, the first insulating film 220 is etched to form a first via anchor region and a movable beam region. In this case, the lower metal wiring 210 is exposed by the first via anchor region. Here, the first via anchor region may correspond to the lower via anchor region. The movable beam region may be formed to extend in the same direction as the lower metal wiring 210 from the upper portion of the lower via anchor region.

Then, referring to FIG. 2B, the conductive material is buried in the first via anchor region and the movable beam region, and a planarization process is performed until the first insulating film 220 is exposed to form the lower via anchor 230 and the movable beam 240.

Then, referring to FIG. 2C, a second insulating film 250 is formed on the entire upper portion, and the second insulating film 250 is etched to form a second via anchor region and an upper metal wiring region. In this case, the second via anchor region is formed to be located on a vertical line with the lower via anchor 230. Here, the second via anchor region may correspond to the upper via anchor region. The upper metal wiring region may be formed on an upper portion of the upper via anchor region.

Then, referring to FIG. 2D, the conductive material is buried in the second via anchor region and the upper metal wiring region formed by etching the second insulating film 250, and the planarization process is performed until the second insulating film 250 is exposed. Through this process, the upper via anchor 260 and the upper metal wiring 270 are formed.

Then, referring to FIG. 2E, the first insulating film 220 and the second insulating film 250 are etched so that an air gap is formed at regular intervals around the movable beam 240. This is to secure the air gap around the movable beam 240 to enable the operation of the movable beam 240. In this case, it is preferable that the second insulating film 250 is etched to expose the upper end of the movable beam 240, and the first insulating film 220 is etched to expose a side surface of the lower via anchor 230.

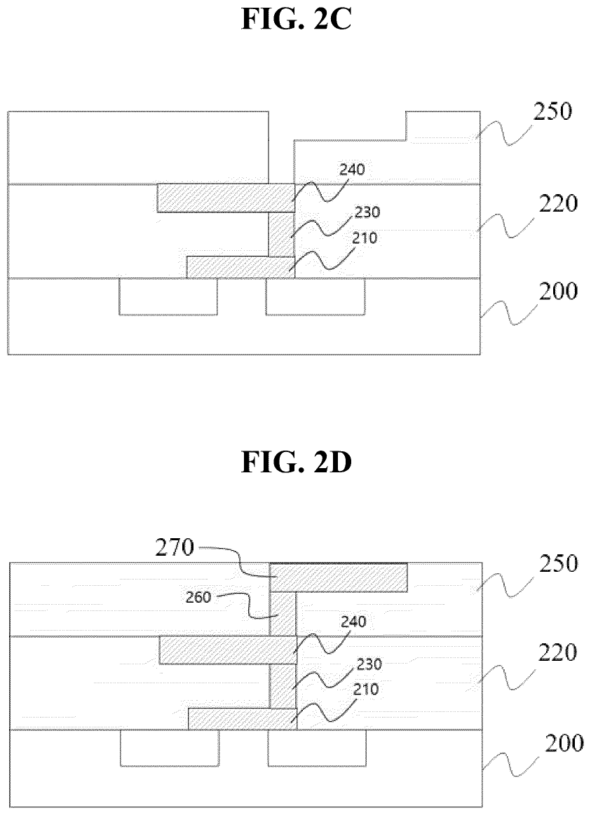

FIG. 3 is a diagram illustrating an operating state of the nano electromechanical device according to the embodiment of the present disclosure.

Referring to FIG. 3, operating states of a nano electromechanical device a having a T-shaped structure and a nano electromechanical device b having a via anchor structure are as follows. First, a driving voltage of the nano electromechanical device a with the T-shaped structure increases as a switching cycle is repeated, which causes excessive stress concentrated on an anchor part A of the movable beam, leading to accumulation of material fatigue. As a result, a softening phenomenon may occur and thus the resilience may be weakened. In addition, mechanical defects such as breakage of the movable beam may occur.

On the other hand, in the nano electromechanical device b having the via anchor structure, the deformation that occurs in the movable beam during operation may be distributed as torsion to the upper via anchor and the lower via anchor like ‘B’, thereby improving durability compared to the device having the T-shaped structure. In addition, since the torsion of the via anchor helps the horizontal movement of the movable beam, the increase in the driving voltage is reduced even if the length of the movable beam is shortened, making it possible to manufacture the nano electromechanical device with a smaller size and lower driving voltage.

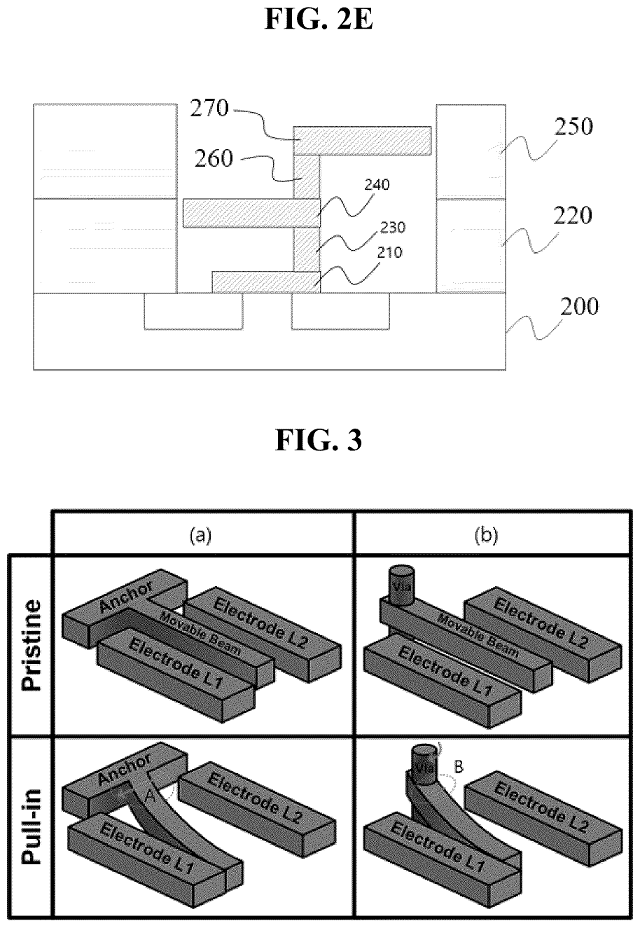

FIG. 4 is a diagram illustrating the degree of stress applied to the anchor part of the nano electromechanical device according to the embodiment of the present disclosure, and illustrates finite element analysis (FEA) results.

Referring to FIG. 4, the stresses applied to the anchor parts of the movable beams of the nano electromechanical device a having the T-shaped structure and the nano electromechanical device b having the via anchor structure may be compared.

Referring to the FEA simulation results in FIG. 4, it can be seen that in the T-shaped structure, a stress concentrated on an anchor part of a movable beam 400 is distributed to an upper via anchor 410a and a lower via anchor 410b. It can be seen that the stress decreases up to 40 to 45% numerically.

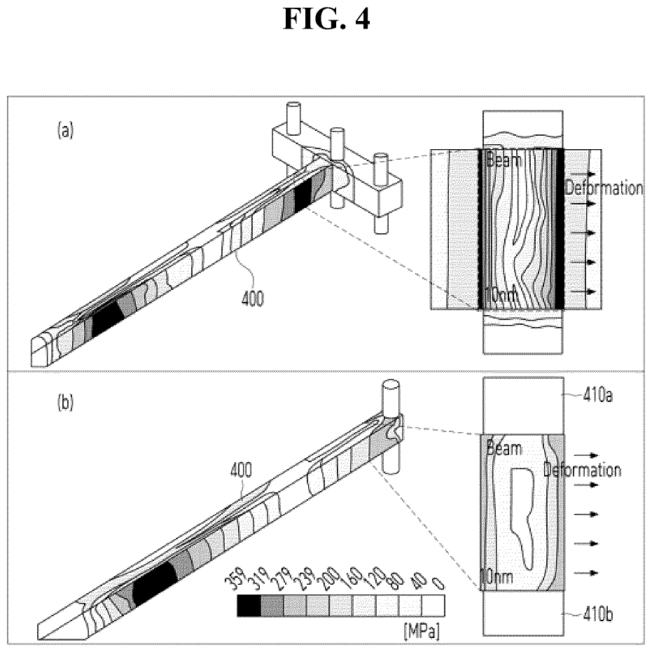

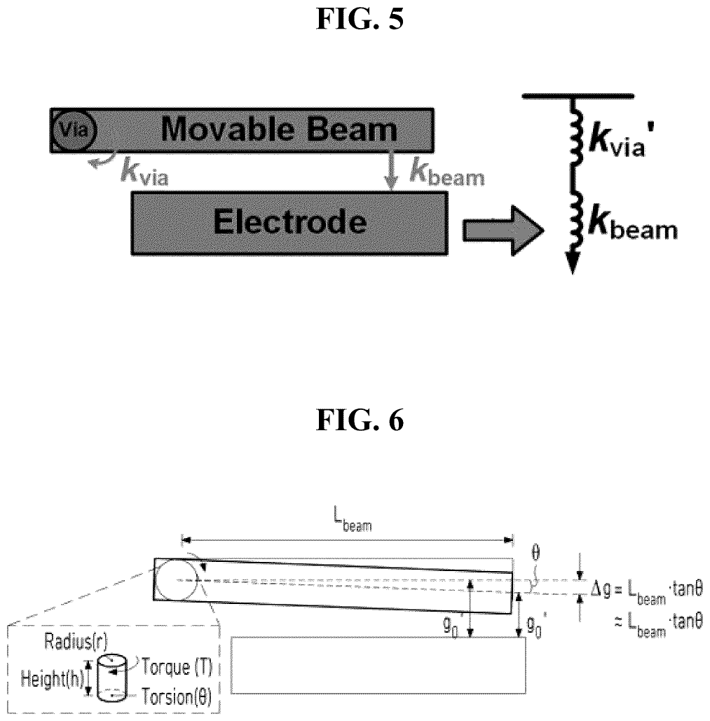

FIG. 5 is a diagram for describing linear spring modeling of the nano electromechanical device according to an embodiment of the present disclosure, and FIG. 6 is a diagram illustrating the effect of a via anchor of the nano electromechanical device on a movable beam according to the embodiment of the present disclosure.

Referring to FIG. 5, the via anchor structure may be replaced with a simple spring model as illustrated in FIG. 5. Here, K_{beam} represents a linear spring constant, and Kᵥᵢₐ represents torsional stiffness. That is, for linear spring modeling as illustrated in FIG. 5, Kᵥᵢₐ must be converted to a spring constant K_{via′}. The spring constant K_{via′} and the linear spring constant K_{beam} can be obtained through <Equation 1> and <Equation 2> below, respectively.

$${k}_{via}^{′} = \frac{π}{2} \frac{{Gr}^{4}}{{hrL}_{beam}} \qquad 〈 Equation 1 〉$$

$${k}_{beam} = \frac{2 {Et}_{beam}}{3} {( \frac{{w}_{beam}}{{L}_{beam}} )}^{3} \qquad 〈 Equation 2 〉$$

Torque T is a product of torsion θ and torsional stiffness, and is a product of the applied force F and a distance r from the point of the force to the axis of rotation. Therefore, when F is obtained through the two equations for the torque, it can be defined as in the <Equation 3> below.

$$F = ( {K}_{via} \cdot θ ) / r , F = {K}_{{via}^{′}} \cdot Δ g \qquad 〈 Equation 3 〉$$

Therefore, K_{via′} may be obtained through <Equation 3>, which is the two Equations of F. In this case, the torsional stiffness Kᵥᵢₐ of the via modeled as a cylinder is defined as a value obtained by dividing a product of the shear modulus G and rotational inertia J by a height h of the cylinder, and as illustrated in FIG. 6, the angle (torsion, θ) caused by the torsion of the via is very small, and therefore, it may be assumed that Δg=L_{beam}·θ.

Therefore, the result of K_{via′} derived as in the model of <Equation 1> may be obtained. As can be seen from the linear spring model, in the T-shaped device structure, only the K_{beam} spring bore the stress, but in the via anchor structure, the K_{via′} spring is added in series, and the force is distributed to two springs, thereby obtaining the effect of distributing the stress to the K_{beam}.

Referring to FIG. 6, when the nano electromechanical device having the via anchor structure operates, the torsion of the via anchor is applied simultaneously with the movement of the movable beam, so unlike the T-shaped structure that relies only on the deformation of the movable beam, the distance between the movable beam and the electrode is reduced by Ag due to the effect of torsion.

Therefore, even if the voltage is the same, the stronger electrostatic force is applied, so the operation is possible with a lower driving voltage Vp. Here, the driving voltage Vp may be obtained through <Equation 4> below.

$${V}_{p} = \sqrt{\frac{16 {Ew}_{beam}^{3}}{81 {ε}_{0} {L}_{beam}^{4}}} \qquad 〈 Equation 4 〉$$

$$( g {0}^{′} = g 0 - Δ g )$$

As a result of the FEA simulation, it can be seen that under the same conditions, the nano electromechanical device having the via anchor structure may operate with the driving voltage reduced by 10 to 20% compared to the T-shaped structure. Therefore, by reducing the length of the movable beam, it is possible to reduce the size of the single device and at the same time manufacture the nano electromechanical device with a lower or equal driving voltage.

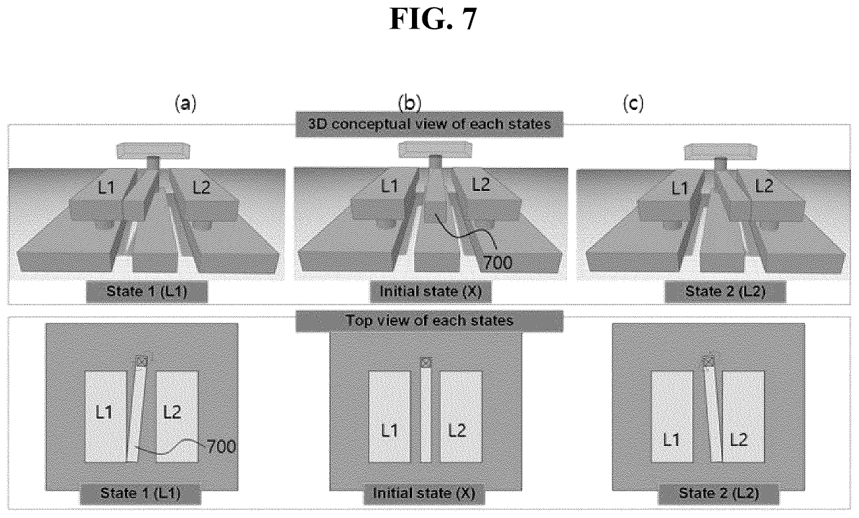

FIG. 7 is a diagram for describing the state of the nano electromechanical device according to the embodiment of the present disclosure.

Referring to FIG. 7, a movable beam 700 maintains an initial state (FIG. 7, (b)) in which the movable beam 700 is not in contact with the first electrode L1 or the second electrode L2, and in the initial state, when the positive voltage V_{L1} or V_{L2} is applied to the first electrode L1 or the second electrode L2, the movable beam 700 may move in the direction of state 1, which is the first electrode L1, or state 2, which is the second electrode L2, by the electromagnetic force generated between metals and therefore change to a state where it is connected to the corresponding electrode (FIGS. 7, (a) and (c)).

The operating principle of this nano electromechanical device is that each electrode and the movable beam exhibit non-volatile characteristics that maintain their stored state even when the voltage supply is cut off due to the adhesion force generated between the connected areas.

As in the embodiment of the present disclosure, when the nano electromechanical device having the via anchor structure is applied to an array such as an associative memory, in the T-shaped structure, when connecting anchors in a 1×8 array, the same metal layers are connected to form a match line and arranged, while in the via anchor structure, it is easy to manufacture an array with greatly reduced space occupancy by vertically integrating the nano electromechanical devices on each layer of M1 to M8 and then setting the vias to be connected as match lines. This has the effect of greatly strengthening the high integration characteristics, which are the strengths of the nano electromechanical device.

Although exemplary embodiments of the present disclosure have been disclosed above, it may be understood by those skilled in the art that the present disclosure may be variously modified and changed without departing from the scope and spirit of the present disclosure described in the following claims.

### DETAILED DESCRIPTION OF MAIN ELEMENTS

| | |
|---|---|
| 110, 240, 400, 700: movable beam | 120: via anchor |
| 120a, 230, 410b: lower via anchor | 120b, 260, 410a: upper via anchor |
| 130, 210: lower metal wiring | 140, 270: upper metal wiring |
| 200: semiconductor structure | |
| 220: first insulating film | 250: second insulating film |

1. A nano electromechanical device, comprising:
a first electrode formed on an upper portion of a metal wiring layer;
a second electrode spaced apart from the first electrode and arranged in parallel;
a movable beam arranged between the first electrode and the second electrode and moving horizontally to contact the first electrode or the second electrode; and
a via anchor connected to upper and lower portions of one side of the movable beam and supporting the movable beam.

2. The nano electromechanical device of claim 1, wherein the via anchor includes:
a lower via anchor connected to a lower end of one side of the movable beam; and
an upper via anchor connected to an upper end of one side of the movable beam and arranged on a vertical line to the lower via anchor.

3. The nano electromechanical device of claim 2, wherein the lower via anchor is formed in a first via anchor region defined at a lower portion of the semiconductor structure and formed by burying a conductive material in a lower via anchor supporter formed of a first insulating film.

4. The nano electromechanical device of claim 3, wherein the upper via anchor is formed in a second via anchor region defined at an upper portion of the semiconductor structure and is formed by burying a conductive material in an upper via anchor supporter formed of a second insulating film.

5. The nano electromechanical device of claim 1, wherein when a positive voltage is applied to the first electrode or the second electrode, the movable beam moves in a direction of the first electrode or the second electrode by electromagnetic force applied between the electrodes to be connected to the corresponding electrode.

6. The nano electromechanical device of claim 5, wherein the via anchor is torsioned at a certain angle in the corresponding direction during a pull-in operation in which the movable beam moves in the direction of the first electrode or the second electrode.

7. The nano electromechanical device of claim 1, wherein the via anchor is torsionable and supports horizontal movement of the movable beam through the torsion.

8. The nano electromechanical device of claim 7, wherein when the movable beam operates, deformation occurring in the movable beam is distributed to the via anchor as the torsion.

9. The nano electromechanical device of claim 1, wherein when a structure of the via anchor is replaced with a spring model, it has a serial structure of a linear spring constant K_{beam} of the movable beam and a spring constant K_{via′} derived from torsional stiffness of the via anchor.

10. A method of manufacturing a nano electromechanical device, comprising:
forming a first insulating film on an upper portion of a semiconductor structure;
forming a lower via anchor and a movable beam by etching the first insulating film and burying a conductive material;
forming a second insulating film on an entire upper portion; and
forming an upper via anchor by etching the second insulating film and burying the conductive material.

11. The method of claim 10, wherein the forming of the lower via anchor and the movable beam includes forming a lower via anchor region by etching the first insulating film to expose a lower metal wiring included in the semiconductor structure.

12. The method of claim 11, wherein the forming of the lower via anchor and the movable beam includes forming a movable beam region extending in the same direction as the lower metal wiring from an upper portion of the lower via anchor region by etching the first insulating film.

13. The method of claim 12, wherein the forming of the lower via anchor and the movable beam includes burying and planarizing a conductive material in the lower via anchor region and the movable beam region.

14. The method of claim 10, wherein the forming of the upper via anchor includes forming an upper via anchor region on a vertical line to the lower via anchor by etching the second insulating film.

15. The method of claim 14, wherein the forming of the upper via anchor includes forming an upper metal wiring region on an upper portion of the upper via anchor region by etching the second insulating film, and burying and planarizing a conductive material in the upper via anchor region and the upper metal wiring region.

16. The method of claim 10, further comprising:
forming an air gap around the movable beam by etching the first insulating film and the second insulating film to expose a side surface of the lower via anchor and an upper end of the movable beam.

17. A method of manufacturing a nano electromechanical device, comprising:
forming a lower metal wiring on an upper portion of a semiconductor structure and forming a first insulating film on an entire upper portion including the lower metal wiring;
forming a first via anchor region and a movable beam region by etching the first insulating film;
forming a lower via anchor and a movable beam by burying a conductive material in the first via anchor region and the movable beam region;
forming a second insulating film on the entire upper portion and forming a second via anchor region and an upper metal wiring region by etching the second insulating film;
forming an upper via anchor and an upper metal wiring by burying the conductive material in the second via anchor region and the upper metal wiring region; and
forming an air gap at regular intervals around the movable beam by etching the first insulating film and the second insulating film adjacent to the movable beam.

18. The method of claim 17, wherein the semiconductor structure includes a plurality of metal wirings.

19. The method of claim 17, wherein the lower via anchor and the upper via anchor are formed on a vertical line.

20. The method of claim 17, wherein the lower via anchor and the upper via anchor are formed to contact one side of the movable beam.
